(19) United States
(12) Patent Application Publication
(10) Pub. No.: US 2024/0204132 A1
(43) Pub. Date: Jun. 20, 2024

(54) OPTOELECTRONIC DEVICE COMPRISING A STACK OF MULTIPLE QUANTUM WELLS

(71) Applicant: COMMISSARIAT À L'ÉNERGIE ATOMIQUE ET AUX ÉNERGIES ALTERNATIVES, Paris (FR)

(72) Inventor: Florian Dupont, Grenoble Cedex 9 (FR)

(73) Assignee: COMMISSARIAT À L'ÉNERGIE ATOMIQUE ET AUX ÉNERGIES ALTERNATIVES, Paris (FR)

(21) Appl. No.: 18/286,894

(22) PCT Filed: Apr. 4, 2022
(86) PCT No.: PCT/EP2022/058878

§ 371 Date: Oct. 13, 2023

(30) Foreign Application Priority Data
Apr. 20, 2021 (FR) 2104097

(51) Int. Cl. H01L 33/06; H01L 33/00; H01L 33/14; H01L 33/32

(52) U.S. Cl. CPC H01L 33/06; H01L 33/007; H01L 33/14; H01L 33/32

(57) ABSTRACT

An optoelectronic device having a stack including an alternation of at least one semiconductor layer of a first material and of semiconductor layers of a second material, each layer of the first material being sandwiched between two layers of the second material and defining a quantum well, wherein the first material is an inorganic perovskite material, and the second material is an inorganic semiconductor material.

The present application is based on, and claims priority from, French patent application No FR2104097 filed on Apr. 20, 2021 and entitled “Dispositif optoélectronique comportant un empilement à puits quantiques multiples”, which is considered an integral part of the present description to the extent permitted by law.

### TECHNICAL AREA

The present description relates generally to optoelectronic devices, and more particularly to an optoelectronic device comprising a multiple-quantum-well stack.

### BACKGROUND ART

Various optoelectronic devices featuring multiple quantum well stacks have been proposed.

A multiple-quantum-well stack is a photon confinement structure for controlling the emission or absorption wavelength of an optoelectronic device. Such a stack typically comprises an alternation of semiconductor layers of a first material and semiconductor layers of a second material, with each layer of the first material sandwiched between two layers of the second material, the first material having a narrower bandgap than the second material.

It would be desirable to improve at least some aspects of optoelectronic devices featuring multiple quantum well stacks.

### SUMMARY OF THE INVENTION

One embodiment provides an optoelectronic device having a stack comprising an alternation of at least one semiconductor layer of a first material and of semiconductor layers of a second material, each layer of the first material being sandwiched between two layers of the second material and defining a quantum well, wherein:
the first material is an inorganic perovskite material; and
the second material is an inorganic semiconductor material.

In one embodiment, the second material comprises a III-V compound.

According to one embodiment, the first material is an inorganic halogen perovskite material.

According to one embodiment, the second material comprises a III-N compound.

According to one embodiment, each layer of the first material has a thickness of between 1 and 20 nm.

According to one embodiment, each layer of the second material has a thickness of between 1 and 100 nm.

According to one embodiment, each layer of the first material has a crystal structure aligned with the crystal structure of the underlying layer of the second material, according to an epitaxial relationship.

According to one embodiment, the device further comprises an LED, the multiple quantum well stack being arranged on one face of the LED and being adapted to convert the light emitted by the LED.

In one embodiment, the LED comprises an emissive active layer sandwiched between a semiconductor layer doped with a first conductivity type and a semiconductor layer doped with a second conductivity type, and the multiple-quantum-well stack coats a face of the semiconductor layer doped with the second conductivity type opposite the emissive active layer.

According to one embodiment, the LED's emissive active layer comprises a multiple-quantum-well stack.

According to one embodiment, the multiple-quantum-well stack forms the active emissive layer of an LED.

According to one embodiment, the LED further comprises an electron transport layer on the side of one face of the multiple-quantum-well stack and a hole transport layer on the side of another face of the multiple-quantum-well stack.

According to one embodiment, the electron transport layer and the hole transport layer are made of inorganic semiconductor materials.

According to one embodiment, the electron transport layer is made of titanium dioxide and the hole transport layer is made of nickel oxide or Spiro-OMeTAD.

According to one embodiment, the stack comprises a plurality of semiconductor layers of the first material.

In a further embodiment, a method is provided for manufacturing an optoelectronic device as defined above, in which layers of the first material and layers of the second material are deposited successively in the same deposition chamber in such a way that each layer of the first material has a crystal structure aligned with the crystal structure of the underlying layer of the second material, according to an epitaxial relationship.

In one embodiment, layers of the first material and layers of the second material are deposited by pulsed laser deposition.

### BRIEF DESCRIPTION OF THE DRAWINGS

These and other features and their advantages will be described in detail in the following non-limiting description of particular embodiments in relation to the accompanying figures, in which:

FIG. 1 is a schematic cross-sectional view of a multiple quantum well stack according to one embodiment;

FIG. 2 is a schematic cross-sectional view showing an example of an optoelectronic device comprising a multiple-quantum-well stack according to one embodiment; and

FIG. 3 is a schematic cross-sectional view of another example of an optoelectronic device comprising a multiple-quantum-well stack according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the described embodiments have been illustrated and described in detail. In particular, the complete realization of the described optoelectronic devices has not been detailed, the realization of these devices being within the capabilities of the person skilled in the art from the indications of the present description. Hereafter, only the realization of multiple quantum well stacks of the optoelectronic devices described has been detailed.

Unless otherwise specified, when reference is made to two elements being connected to each other, this means directly connected without any intermediate elements other than conductors, and when reference is made to two elements being “coupled” to each other, this means that these two elements may be connected or may be connected via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the figures.

Unless otherwise specified, the expressions “about”, “approximately”, “substantially”, and “of the order of” mean to within 10%, preferably to within 5%.

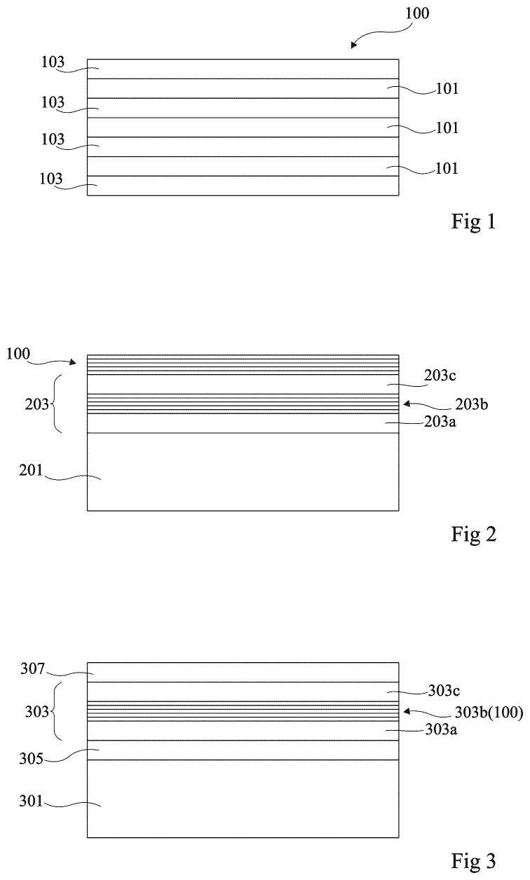

FIG. 1 is a schematic cross-sectional view of a multiple-quantum-well stack 100 in one embodiment.

Stack 100 comprises one or more alternating semiconductor layers 101 of a first material and semiconductor layers 103 of a second material, each layer 101 of the first material being sandwiched between two layers 103 of the second material. More specifically, each layer 101 is in contact, by its lower face, with the upper face of one layer 103, and, by its upper face, with the lower face of another layer 103. Thus, if N designates the number of layers 101, the number of layers 103 is equal to N+1.

The 101 layer material has a narrower bandgap than the 103 layer material.

Each first layer 101 defines a quantum well. Layers 103 are quantum barriers.

The number N of quantum wells in the stack is preferably greater than or equal to 2. In the example shown, N is equal to 3. However, the described embodiments are not limited to this particular case. Alternatively, the number N of quantum wells in the stack may be greater than 3.

Such a multi-quantum-well stack can, for example, be used as a photoluminescent conversion element in an emissive device, such as an image display screen or lighting device. In this case, the stack is placed opposite an emission face of a light source, such as a light-emitting diode. The stack is then adapted to absorb photons at the emission wavelength of the light source, and to re-emit photons at another wavelength.

Alternatively, a multiple-quantum-well stack of the type described in relation to FIG. 1 can be used as the active (self-emitting) layer of a light source, such as a light-emitting diode.

According to one aspect of the described embodiments, the material of the layers 101 is a perovskite-structure material.

One advantage is that materials with a perovskite structure, hereinafter referred to as perovskite materials, have a high internal quantum efficiency of up to 100%.

Another advantage is that perovskite materials have a high absorption coefficient.

Another advantage is that perovskite materials can be deposited at relatively low temperatures, e.g. below 400° ° C., enabling them to be deposited on top of a CMOS (Complementary Metal Oxide Semiconductor) integrated circuit.

Because of the low thicknesses required to ensure the desired light conversion or emission functions, layers 101 and 103 can be easily etched, enabling the production of light conversion or emission elements with very small lateral dimensions.

As a result, multiple quantum well stacks based on perovskite materials are particularly advantageous for the realization of light conversion or emission elements in small pixels, for example for the realization of color image display screens with an inter-pixel pitch of less than 100 μm, for example less than 20 μm, or even less than 5 μm.

To obtain good conversion or light emission performance and long life, the material of layer 101 is preferably an inorganic perovskite material.

For example, a perovskite material based on cesium, lead and one or more halogens may be used, such as CsPbI₂Br, CsPbBr₃, CsPbCl₃, or CsPbI₃. Alternatively, a perovskite material of the MAPbI₃ type may be used. More generally, other perovskite materials can be chosen depending on the conversion or emission properties required.

In general, a perovskite material known as inorganic halogen is preferred, i.e. of the type ABX₃, where:
A is an inorganic element, for example cesium (Cs), lead (Pb), phosphorus (K) or lithium (Li),
B is lead (Pb), tin (Sn) or germanium (Ge), and
X is a halogen, for example bromine (Br), chlorine (CI), iodine (I) or a combination of halogens.

The barrier layer material 103 is preferably an inorganic semiconductor material. Preferably, layer material 103 comprises a III-V compound comprising at least a first group III element, a second group V element and, optionally, a third element, for example a group III element other than the first element. By way of example, the Group V element is nitrogen (N). In other words, layer material 103 comprises a III-N compound. For example, layer material 103 is gallium nitride (GaN), aluminum nitride (AlN), boron nitride (BN), indium nitride (InN) or an alloy of one or more of these materials.

The stack shown in FIG. 1 is preferably formed by epitaxial growth. This produces single-crystal layers 101, which have the advantage of being more stable over time than polycrystalline perovskite layers. In addition, encapsulating the layers 101 with epitaxial inorganic layers 103 improves the long-term stability of the perovskite material, in particular by avoiding exposure of the perovskite material to oxygen. In addition, epitaxial growth of the stack creates stresses in layers 101 and 103, which improves the long-term stability of perovskite material layers 101, in particular by preventing halogen segregation under the effect of exposure to light.

Preferably, layers 101 and 103 of the stack are successively deposited by PLD (Pulsed Laser Deposition), also known as pulsed laser ablation deposition. PLD involves sputtering or ablating the surface of a target of the material to be deposited by means of a pulsed laser, so as to transfer the material into a plasma and then, via the plasma, onto the target substrate. One advantage of PLD deposition is that it enables complex materials such as perovskite materials to be deposited with good crystalline quality, and this at a relatively low temperature, for example below 400° ° C., without damaging the destination substrate. Preferably, layers 101 and 103 are successively deposited by PLD without changing the deposition equipment and without removing the destination substrate from the deposition chamber between two successive deposition steps. Indeed, one advantage of PLD deposition is that it enables switching between different material targets of different compositions without extracting the destination substrate from the deposition chamber. This means that the different layers of the stack are not exposed to air or oxygen between successive deposits. Another advantage is that PLD deposition is a gentle deposition method. In other words, PLD deposition is characterized by a “soft landing” of the target atoms on the destination substrate. In particular, this prevents damage to the perovskite material of the layers 101 during deposition of the barrier layers 103.

The thickness of the layers 101 is chosen to enable quantum confinement in each layer 101. For example, each layer 101 has a thickness of between 1 and 20 nm. For example, each barrier layer 103 has a thickness of between 1 and 100 nm.

FIG. 2 is a schematic cross-sectional view of an example of an optoelectronic device comprising a multiple quantum well stack 100 of the type described in connection with FIG. 1. The device in FIG. 2 is an LED emissive cell, defining for example a pixel of an LED emissive display screen.

The device shown in FIG. 2 comprises a support substrate 201, for example made of sapphire or silicon, and an LED 203 arranged on the upper face of substrate 201. In this example, LED 203 comprises a stack including, in order from the top face of substrate 201, a semiconductor layer 203a doped with a first conductivity type, an emissive active layer 203b, and a semiconductor layer 203c doped with a second conductivity type. In this example, layers 203a and 203c are doped with N-type and P-type respectively, and form the cathode and anode of LED 203 respectively. Alternatively, layers 203a and 203c can be interchanged. In this example, emissive layer 203b is a multiple quantum well stack consisting of alternating quantum well layers of a first material and barrier layers of a second material. By way of example, each of the first and second materials predominantly comprises a III-V compound comprising at least a first group III element, a second group V element and, optionally, a third element, for example a group III element other than the first element. Each quantum well is made of gallium nitride, for example. In the example shown, the lower face of layer 203b is in contact with the upper face of layer 203a, and the upper face is in contact with the lower face of layer 203c.

In the device shown in FIG. 2, stack 100 is arranged on the top face of LED 203. In this example, stack 100 is a photoluminescent conversion stack adapted to absorb photons at the emission wavelength of LED 203, and to re-emit photons at another wavelength. This converts the light emitted by LED 203. The result is an emissive cell emitting at a wavelength different from the emission wavelength of LED 203.

By way of example, layers 203a, 203b and 203c of LED 203 are formed successively by epitaxy, such as MOCVD (Metalorganic Chemical Vapour Deposition), on the top surface of substrate 201. Stack 100 can then be formed by PLD deposition on and in contact with the top surface of layer 203c.

Alternatively (not shown), once the LED stack 203 has been formed, it can be transferred to a transfer substrate, such as an integrated circuit for controlling the LEDs, e.g. a CMOS circuit. In this case, the top face (in the orientation shown in FIG. 2) of layer 203c faces the transfer substrate and abuts one face of the transfer substrate. The growth substrate 201 can then be removed, exposing the face of layer 203a opposite the transfer substrate. Stack 100 can then be formed by PLD deposition on and in contact with the face of layer 203c opposite the transfer substrate.

As a non-limiting example, the LED 203 is adapted to emit predominantly blue light, and the stack 100 is adapted to convert the blue light emitted by the LED into predominantly red light. To this end, the quantum well layers 101 of the stack 100 are made, for example, of CsPbI₃. e.g. with a thickness of around 7 nm, and the barrier layers 103 of the 100 stack are made, for example, of GaN, e.g. unintentionally doped GaN, e.g. with a thickness of around 15 nm.

FIG. 3 is a cross-sectional view schematically depicting another example of an optoelectronic device comprising a multiple quantum well stack 100 of the type described in connection with FIG. 1. Again, the device of FIG. 3 is an LED emissive cell, defining for example a pixel of an LED emissive display screen.

The device shown in FIG. 3 comprises a supporting substrate 301, for example made of sapphire or silicon, and an LED 303 arranged on the top face of the substrate 301. In this example, the LED 303 comprises a stack comprising, in this order from the top face of the substrate 301, a first charge transport layer 303a, an active emissive layer 303b, and a second charge transport layer 303c. In this example, the emissive layer 303b consists of a stack of multiple quantum wells 100 based on perovskite material of the type described in relation to FIG. 1. In the example shown, the layer 303b is in contact, by its lower face, with the upper face of the layer 303a, and, by its upper face, with the lower face of the layer 303c. By way of example, layer 303a is an electron-transport layer and layer 303c is a hole-transport layer. The layer 303a is made, for example, of titanium dioxide (TiO₂). The layer 303c is made, for example, of nickel oxide (NiO). Alternatively, the layer 303c is made of Spiro-OMeTAD (C₈₁H₆₈N₄O₈). Layers 303a and 303c enable current to be injected into the stack 100 to cause the LED to emit light. Alternatively, layers 303a and 303c can be exchanged.

In the example shown in FIG. 3, the device also includes a reflective metal layer 305, also known as a mirror layer, between the upper face of the substrate 301 and the LED 303. More specifically, in the example shown, layer 305 is in contact, by its lower face, with the upper face of substrate 301, and, by its upper face, with the lower face of layer 303a. Layer 305 is made of platinum, for example. Layer 305 enables the light emitted by the LED to be reflected towards the emission side of the device, i.e. its top side in this example. Layer 305 also forms, in this example, a lower electrode of the LED.

In the example shown in FIG. 3, the device further comprises a conductive layer 307, transparent to the LED's emission wavelength, arranged on the top side of layer 303c, for example on and in contact with the top side of layer 303c. The conductive layer 307 forms a top electrode of the LED. Layer 307 is made, for example, of a transparent conductive oxide, such as indium tin oxide (ITO), or zinc oxide (ZNO). Layer 307 can be doped with aluminum or cadmium. Layer 307 can be covered with a passivation layer, not shown, e.g. of silicon nitride.

The result is an emissive cell emitting at a wavelength that depends on the composition of the multiple-quantum-well stack 100. By way of example, LED 303 is adapted to emit predominantly red light. To this end, the quantum well layers 101 of the stack 100 are, for example, made of CsPbI₃, e.g. with a thickness of around 7 nm, and the barrier layers 103 of the stack 100 are, for example, made of GaN, e.g. unintentionally doped GaN, e.g. with a thickness of around 15 nm.

By way of example, layers 305 and 303a are first formed successively on the top face of substrate 301, for example by ALD (Atomic Layer Deposition) or any other suitable deposition method. The stack 100 can then be formed on the top surface of layer 303a, for example by PLD deposition. Layers 303c and 307 are then successively formed on the top face of stack 100, for example by ALD deposition or any other suitable deposition method.

Various embodiments and variants have been described. The person skilled in the art will understand that certain features of these various embodiments and variants could be combined, and other variants will become apparent to the person skilled in the art. In particular, the embodiments described are not limited to the examples of materials and dimensions mentioned in the present description.

Furthermore, although examples of the integration of multiple quantum well stacks based on perovskite materials into a pixel of an LED display device have been described above, the embodiments described are not limited to this particular application. Alternatively, multiple-quantum-well conversion stacks based on perovskite materials of the type described above can be used in LED lighting devices, or in photodetection devices, e.g. photodiodes.

Furthermore, although examples of the integration of multiple-quantum-well stacks based on perovskite materials in emissive devices based on planar LEDs have been described above, the embodiments can be adapted to emissive devices based on three-dimensional LEDs, e.g. LEDs based on semiconductor nanowires or microwires, or pyramidal LEDs, e.g. micro or nano pyramidal LEDs, e.g. of the type described in patent application FR3087942 or patent application FR3089687 previously filed by the applicant. A planarization step of the device surface can optionally be provided prior to deposition of the multiple quantum well stack based on a perovskite material. For example, if the multiple-quantum-well stack based on a perovskite material is a quantum converter, the latter can be deposited either directly on the three-dimensional LEDs, or on the top surface of a transparent planarization layer previously deposited on the three-dimensional LEDs.

Furthermore, although only examples of embodiments have been described above in which the barrier layers 103 of the multiple quantum well stack based on perovskite material are made of a III-V compound, the embodiments described are not limited to this particular case. More generally, the layers 103 can be made of any inorganic semiconductor material, such as IV-IV material, e.g. silicon carbide (SiC), or II-VI material, e.g. zinc oxide (ZnO).

1. Optoelectronic device comprising a control integrated circuit and, on one side of said integrated circuit, a stack comprising an alternation of at least one semiconductor layer of a first material and of semiconductor layers of a second material, each layer of the first material being sandwiched between two layers of the second material and defining a quantum well, wherein:
the first material is an inorganic perovskite material; and
the second material is an inorganic semiconductor material.

2. The optoelectronic device of claim 1, wherein the second material comprises a III-V compound.

3. The optoelectronic device of claim 1, wherein the first material is an inorganic halogen perovskite material.

4. An optoelectronic device according to claim 1 in which the second material comprises a III-N compound.

5. A device according to claim 1, wherein each layer of the first material has a thickness of between 1 and 20 nm.

6. A device according to claim 1, wherein each layer of the second material has a thickness of between 1 and 100 nm.

7. A device according to claim 1, in which each layer of the first material has a crystal structure aligned with the crystal structure of the underlying layer of the second material, according to an epitaxial relationship.

8. A device according to claim 1, further comprising an LED on said face of the control integrated circuit, the multiple quantum well stack being disposed on a face of the LED opposite the control integrated circuit and being adapted to convert the light emitted by the LED.

9. A device according to claim 8, wherein the LED comprises an emissive active layer sandwiched between a semiconductor layer doped with a first conductivity type and a semiconductor layer doped with a second conductivity type, and wherein the multi-quantum-well stack coats a face of the semiconductor layer doped with the second conductivity type opposite the emissive active layer.

10. A device according to claim 9, wherein the active emissive layer of the LED comprises a multiple quantum well stack.

11. A device according to claim 1, wherein the multiple quantum well stack constitutes an active emissive layer of an LED disposed on said face of the control integrated circuit.

12. A device according to claim 11 in which the LED further comprises an electron-transport layer on the side of one face of the multiple-quantum-well stack and a hole-transport layer on the side of another face of the multiple-quantum-well stack.

13. Device according to claim 12, wherein the electron transport layer and the hole transport layer are made of inorganic semiconductor materials.

14. Device according to claim 12, wherein the electron transport layer is made of titanium dioxide and wherein the hole transport layer is made of nickel oxide or Spiro-OMeTAD.

15. A device according to claim 1, wherein the stack comprises a plurality of semiconductor layers of the first material.

16. A method of manufacturing an optoelectronic device according to claim 1, in which layers of the first material and layers of the second material are deposited successively in the same deposition chamber in such a way that each layer of the first material has a crystal structure aligned with the crystal structure of the underlying layer of the second material, according to an epitaxial relationship.

17. The method of claim 16, in which the layers of the first material and the layers of the second material are deposited by pulsed laser deposition.

18. The method of claim 16, further comprising an LED on said face of the control integrated circuit, the multiple quantum well stack being disposed on a face of the LED opposite the control integrated circuit and being adapted to convert the light emitted by the LED and comprising a step of transferring the LED onto said face of the integrated control circuit, the stack being deposited on the face of the LED opposite the integrated control circuit, after said transfer step.
